(19) United States
(12) Patent Application Publication
(10) Pub. No.: US 2012/0235271 A1
(43) Pub. Date: Sep. 20, 2012

(54) SOLID-STATE IMAGE SENSING DEVICE

(75) Inventor: Hisayo MOMOSE, Kanagawa (JP)

(73) Assignee: Kabushiki Kaisha Toshiba, Tokyo (JP)

(21) Appl. No.: 13/419,082

(22) Filed: Mar. 13, 2012

(30) Foreign Application Priority Data
Mar. 14, 2011 (JP) 2011-055031

(51) Int. Cl. H01L 31/02

(52) U.S. Cl. 257/447; 257/E31.11

(57) ABSTRACT

According to one embodiment, there is provided a solid-state image sensing device including a photodiode in which a semiconductor region of a first conductivity type formed on a substrate and a semiconductor region of a second conductivity type which is different from the first conductivity type is made as a PN junction. The semiconductor region of the first conductivity type has a first semiconductor region and a plurality of second semiconductor regions. Either of the first semiconductor region and each of the second semiconductor regions is formed by a material containing Si as a main component. The other of the first semiconductor region and each of the second semiconductor regions is formed by a material containing Si₁₋ₓGeₓ (0<x≦1) as a main component. Each of the plurality of second semiconductor regions is provided in a shape of an island over the first semiconductor region.

### CROSS-REFERENCE TO RELATED APPLICATIONS

This application is based upon and claims the benefit of priority from Japanese Patent Application No. 2011-055031, filed on Mar. 14, 2011; the entire contents of which are incorporated herein by reference.

### FIELD

Embodiments described herein relate generally to a solid-state image sensing device.

### BACKGROUND

In recent years, a pixel size has been reduced radically based on requests for a reduction in a size and an increase in the number of pixels which are given to a solid-state image sensing device. In particular, a reduction in a size and an increase in the number of pixels in a camera module are required to be compatible with each other. For this reason, a finer pixel size is strongly required in a solid-state image sensing device which is intended for a portable telephone having a camera function.

Each pixel in the solid-state image sensing device has a photodiode to be a photoelectric converting region in a silicon substrate, and a signal charge subjected to a photoelectric conversion is amplified by an amplifying element incorporated in a pixel and is thus fetched as a voltage or a current.

### BRIEF DESCRIPTION OF THE DRAWINGS

FIGS. 1A to 1C are views showing a structure of a solid-state image sensing device according to a first embodiment;

FIGS. 2A to 2D are views showing a method of manufacturing the solid-state image sensing device according to the first embodiment;

FIGS. 3A and 3B are views showing a structure of a solid-state image sensing device according to a second embodiment;

FIGS. 4A to 4D are views showing a method of manufacturing the solid-state image sensing device according to the second embodiment;

FIGS. 5A to 5C are views showing a structure of a solid-state image sensing device according to a third embodiment and a method of manufacturing the same;

FIGS. 6A and 6B are views showing a structure of a solid-state image sensing device according to a fourth embodiment;

FIG. 7 is a view showing a structure of a solid-state image sensing device according to a fifth embodiment;

FIG. 8 is a view showing a structure of a solid-state image sensing device according to a sixth embodiment; and

FIG. 9 is a chart showing optical absorption coefficients and penetration depths of silicon and germanium.

### DETAILED DESCRIPTION

In general, according to one embodiment, there is provided a solid-state image sensing device including a photodiode in which a semiconductor region of a first conductivity type formed on a substrate and a semiconductor region of a second conductivity type which is different from the first conductivity type is made as a PN junction. The semiconductor region of the first conductivity type has a first semiconductor region and a plurality of second semiconductor regions. Either of the first semiconductor region and each of the second semiconductor regions is formed by a material containing Si as a main component. The other of the first semiconductor region and each of the second semiconductor regions is formed by a material containing Si₁₋ₓGeₓ (0<x≦1) as a main component. Each of the plurality of second semiconductor regions is provided in a shape of an island over the first semiconductor region.

Exemplary embodiments of a solid-state image sensing device will be explained below in detail with reference to the accompanying drawings. The present invention is not limited to the following embodiments.

### First Embodiment

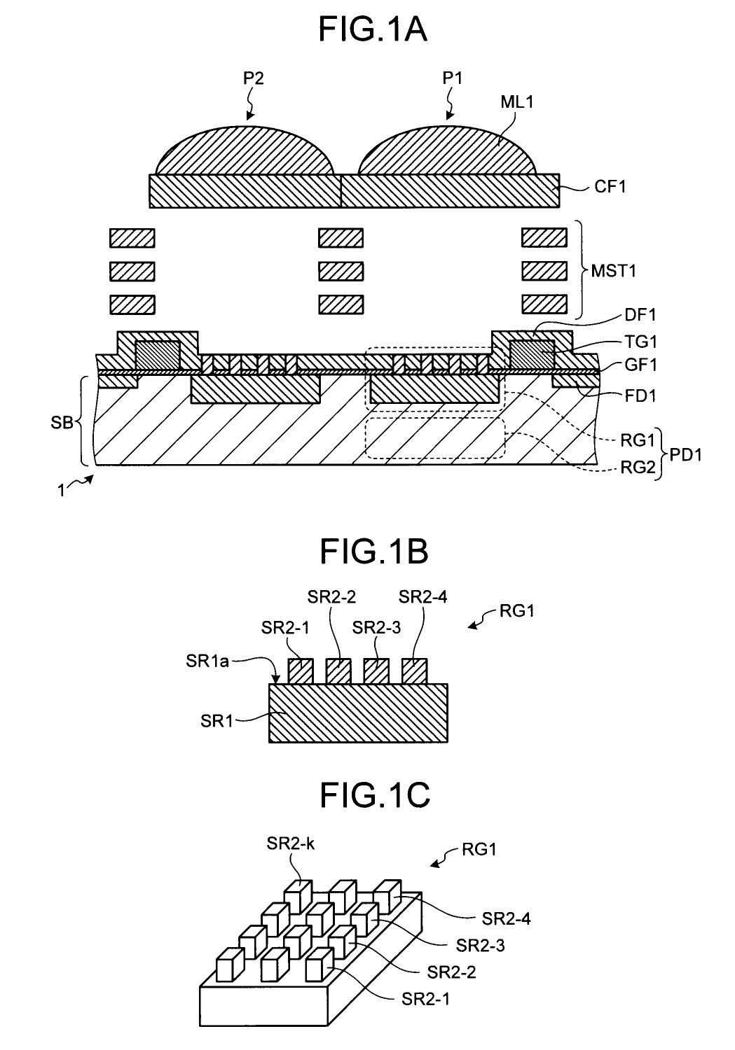

A solid-state image sensing device 1 according to a first embodiment will be described with reference to FIG. 1A. FIG. 1A is a view showing a sectional structure for two pixel portions including pixels P1 and P2 in the solid-state image sensing device 1. In the solid-state image sensing device 1, a plurality of pixels including the pixels P1 and P2 are arranged in one-dimensionally or two-dimensionally. A structure of the pixel P1 will be mainly described below, and a structure of the pixel P2 or the like is the same as that of the pixel P1.

The pixel P1 in the solid-state image sensing device 1 includes a microlens ML1, a color filter CF1, a multilayer wiring structure MST1, a photodiode PD1, an insulating film DF1, a gate insulating film CF1, a gate electrode TG1, and a floating diffusion FD1.

The microlens ML1 is provided on the color filter CF1. The microlens ML1 collects incident light onto a light receiving surface of the photodiode PD1 via the color filter CF1.

The color filter CF1 is provided on the multilayer wiring structure MST1. The color filter CF1 selectively causes a type of light, which is led from the microlens ML1 and has a wavelength region for a specific color (for example, red, green, blue or the like), to pass therethrough.

The multilayer wiring structure MST1 is provided on the insulating film DF1 so as not to be superposed on the photodiode PD1.

The photodiode PD1 is provided in a semiconductor substrate SB. The photodiode PD1 has a PN junction region in which a region RG1 of a first conductivity type (for example, an N type) and a region RG2 of a second conductivity type (for example, a P type) are made as a PN junction. The second conductivity type is reverse to the first conductivity type. For example, in the photodiode PD1, the region RG1 of the first conductivity type is bonded onto the region RG2 of the second conductivity type. For instance, the region RG2 of the second conductivity type forms a part of the region of the second conductivity type in the semiconductor substrate SB, and is formed by a semiconductor (for example, a material containing Si as a main component) containing an impurity of the second conductivity type (for example, the P type) in a low concentration. The impurity of the P type is boron, for example. The region RG1 of the first conductivity type is formed by a semiconductor containing an impurity of the first conductivity type (for example, the N type) in a higher concentration than that of the impurity of the second conductivity type, for instance. The Impurity of the N type is phosphorus or arsenic, for example. The photodiode PD1 carries out a photoelectric conversion in the region RG1 of the first conductivity type over the light which is led, and generates and stores an electric charge corresponding to a light quantity.

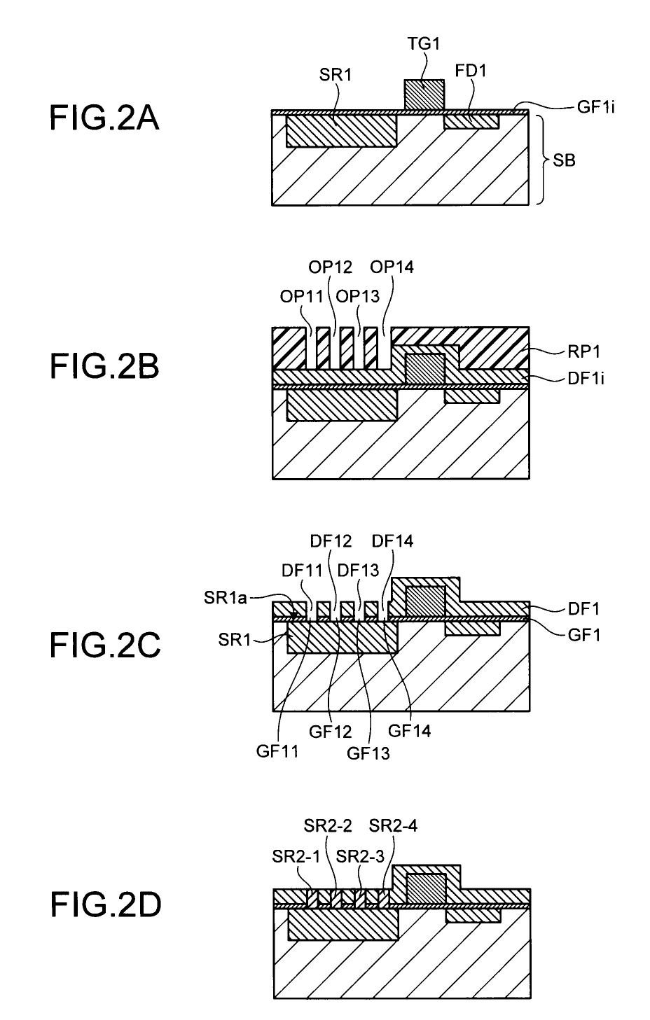

The insulating film DF1 covers the photodiode PD1, the gate electrode TG1 and the gate insulating film GF1. The insulating film DF1 has a plurality of holes DF11 to DF14 (see FIG. 2C) through which a part of the photodiode PD1 penetrates in the regions corresponding to the photodiode PD1.

The gate insulating film GF1 covers a surface of the semiconductor substrate SB and insulates the gate electrode TG1 from the semiconductor substrate SB. Moreover, the gate insulating film GF1 has a plurality of holes GF11 to GF14 (see FIG. 2C) through which a part of the photodiode PD1 penetrates in the regions corresponding to the photodiode PD1. The holes GF11 to GF14 are formed corresponding to the holes DF11 to DF14 in the insulating film DF1.

The gate electrode TG1 is disposed in a position adjacent to the photodiode PD1 on the gate insulating film GF1. The gate electrode TG1 constitutes a transfer transistor together with the photodiode PD1 and the floating diffusion FD1. The transfer transistor is turned ON when a control signal having an active level is supplied to the gate electrode TG1, thereby transferring the electric charge stored in the photodiode PD1 to the floating diffusion FD1.

The floating diffusion FD1 is provided in the semiconductor substrate SB. The floating diffusion FD1 is formed by a semiconductor (for example, a material containing Si as a main component) containing an impurity of the first conductivity type (for example, the N type) in a higher concentration than that of an impurity of the second conductivity type in a well region. The impurity of the N type is phosphorus or arsenic, for example. The electric charge stored in the floating diffusion FD1 is transferred through a transfer transistor and is converted into a voltage. An amplifying transistor which is not illustrated outputs, to a signal line, a signal corresponding to the converted voltage.

Next, a structure in the photodiode PD1 will be described.

In the photodiode PD1, the region RG1 of the first conductivity type (for example, the N type) is bonded onto the region RG2 of the second conductivity type (for example, the P type) as shown in FIG. 1A. FIG. 1B shows an extracted view of the region RG1 of the first conductivity type in FIG. 1A. FIG. 10 is a perspective view showing the region RG1 of the first conductivity type.

As shown in FIGS. 1B and 1C, the region RG1 of the first conductivity type has a first semiconductor region SR1 and a plurality of second semiconductor regions SR2-1 to SR2-k (k represents an integer). In other words, all of the first semiconductor region SR1 and the second semiconductor regions SR2-1 to SR2-k are semiconductor regions containing the impurity of the first conductivity type.

The first semiconductor region SR1 is provided in the semiconductor substrate SB (see FIG. 1A). The first semiconductor region SR1 is formed by a semiconductor (for example, a material containing Si as a main component) containing the impurity of the first conductivity type (for example, the N type) in a higher concentration than that of the impurity of the second conductivity type RG2. The impurity of the N type is phosphorus or arsenic, for example. The first semiconductor region SR1 is provided in contact with the region RG2 of the second conductivity type and forms a PN junction region together with the region RG2 of the second conductivity type.

The second semiconductor regions SR2-1 to SR2-k are provided on the first semiconductor region SR1. The second semiconductor regions SR2-1 to SR2-k are formed by a semiconductor containing the impurity of the first conductivity type (for example, the N type) in a high concentration than that of the impurity of the second conductivity type.

More specifically, the second semiconductor regions SR2-1 to SR2-k are constituted by a semiconductor material which is different from that of the first semiconductor region SR1. For instance, the first semiconductor region SR1 is silicon and each of the second semiconductor regions SR2-1 to SR2-k is formed by a semiconductor layer (for example, a material containing Si₁₋ₓGeₓ (0<x≦1) as a main component) which is different from the first semiconductor region.

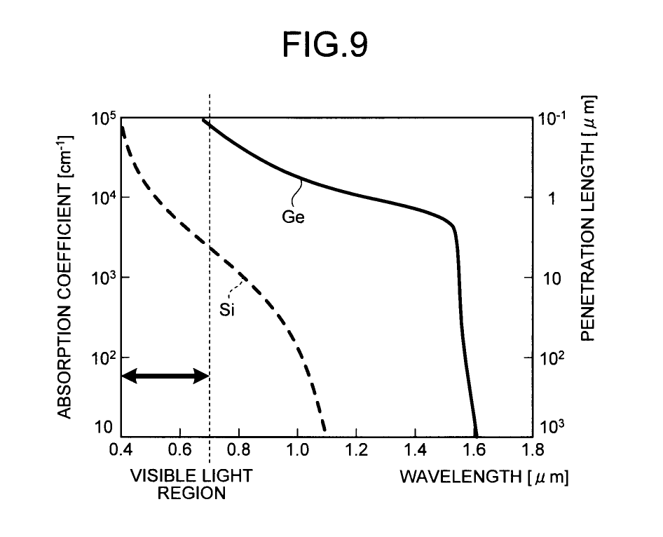

If Si₁₋ₓGeₓ (0≦x≦1) is selected as the material of the second semiconductor regions SR2-1 to SR2-k, for example, an average absorption coefficient has a value between an absorption coefficient of Si shown in a broken line and that of Ge shown in a solid line in FIG. 9, and a photoelectric conversion efficiency of the whole photodiode PD1 is enhanced more greatly than that in the case in which a photoelectric converting portion is formed by only the silicon. For example, a Ge layer containing no Si may be selected as the material of the second semiconductor regions SR2-1 to SR2-k, for example. In this case, the absorption coefficient of Ge is great. Therefore, the photoelectric conversion efficiency of the photodiode PD1 can be further enhanced.

Moreover, each of the second semiconductor regions SR2-1 to SR2-k is provided in a shape of an island over the first semiconductor region SR1. In other words, the second semiconductor regions SR2-1 to SR2-k are respectively provided apart from each other over the first semiconductor region SR1. The second semiconductor regions SR2-1 to SR2-k are arranged two-dimensionally over the first semiconductor region SR1, for example (see FIG. 10). The second semiconductor regions SR2-1 to SR2-k are formed in a convex shape over a surface SR1a of the first semiconductor region SR1. In other words, the second semiconductor regions SR2-1 to SR2-k penetrate through the gate insulating film GF1 and the insulating film DF1 from the surface SR1a of the first semiconductor region SR1 via the holes GF11 to GF14 of the gate insulating film GF1 and the holes DF11 to DF14 of the insulating film DF1, and are thus extended upward.

More specifically, the second semiconductor regions SR2-1 to SR2-k have a maximum width of 0.1 μm or less in a direction along the surface SR1a of the first semiconductor region SR1. For example, bottom surfaces of the second semiconductor regions SR2-1 to SR2-k have a maximum width of 0.1 μm or less. In the case in which the second semiconductor regions SR2-1 to SR2-k take a shape of a prism shown in FIGS. 1B and 1C, for example, both a diagonal line and a long side of the bottom surface are equal to or smaller than 0.1 μm.

If the maximum width in the direction along the surface SR1a of the first semiconductor region SR1 in each of the second semiconductor regions SR2-1 to SR2-k is greater than 0.1 μm, a lattice mismatch of a crystal of the first semiconductor region SR1 (for example, a material containing Si as a main component) and a crystal of each of the second semiconductor regions SR2-1 to SR2-k (for example, a material containing Si₁₋ₓGeₓ (0<x≦1) as a main component) cannot be completely absorbed in both of them. Consequently, there is a tendency that a crystal defect (dislocation) in an interface between the first semiconductor region SR1 and each of the second semiconductor regions SR2-1 to SR2-k is generated.

The second semiconductor regions SR2-1 to SR2-k may take a cylindrical shape. In this case, each of the second semiconductor regions SR2-1 to SR2-k has a diameter of the bottom surface which is equal to or smaller than 0.1 μm. Alternatively, each of the second semiconductor regions SR2-1 to SR2-k may take a shape of an elliptic cylinder. In this case, each of the second semiconductor regions SR2-1 to SR2-k has the diameter of the bottom surface which is equal to or smaller than 0.1 μm.

When Ge is selected as the material of each of the second semiconductor regions SR2-1 to SR2-k, for example, a lattice constant of Ge is 0.565 nm and a lattice mismatch is caused between each of the second semiconductor regions SR2-1 to SR2-k and the first semiconductor region SR1 due to a difference from a lattice constant of 0.543 nm in Si. If Si₁₋ₓGeₓ (0≦x≦1) is selected as the material of each of the second semiconductor regions SR2-1 to SR2-k, for example, an average interval between crystal lattices has a value between 0.543 nm and 0.565 nm, which are lattice constants of Si and Ge, respectively.

Next, a method of manufacturing the solid-state image sensing device 1 will be described with reference to FIGS. 2A to 2D and FIG. 1A. FIGS. 2A to 2D are sectional views showing a process for the method of manufacturing the solid-state image sensing device 1. FIG. 1A is a view showing the structure of the solid-state image sensing device 1, and is diverted as a drawing illustrating a step shown in FIG. 2D. Although description will be given to the second semiconductor regions SR2-1 to SR2-4, among the second semiconductor regions SR2-1 to SR2-k, which are arranged two-dimensionally over the surface SR1a of the first semiconductor region SR1, for example, the same manner is applied to the other second semiconductor regions.

In a step shown in FIG. 2A, a gate insulating film GFli is formed on the surface of the semiconductor substrate SB, and a conductor substance is then deposited to form the gate electrode TG1 in a desired region on the gate insulating film GF1i. As the conductor substance forming the gate electrode TG1, for example, a Si based material doped previously into the N type or the P type, a metal, an alloy or the like is used.

Thereafter, a resist pattern (not shown) having an opening pattern is provided in a region of the second conductivity type in the semiconductor substrate SB in which the first semiconductor region SR1 is to be formed by way of ion implantation or the like, and an impurity of the first conductivity type is introduced into a well region of the second conductivity type by using the resist pattern as a mask. Also in a region in which the floating diffusion of the first conductivity type is to be formed, moreover, a resist pattern (not shown) is formed to introduce an impurity of the first conductivity type. Subsequently, a heat treatment for impurity activation is carried out to form the first semiconductor region SR1 and the floating diffusion FD1. The first semiconductor region SR1 is to serve as a part of the photodiode PD1 (see FIG. 1A).

In a step shown in FIG. 2B, an insulating film DF1i for covering the gate insulating film GFli and the gate electrode TG1 is deposited by a CVD process or the like. The insulating film DF1i is formed in a film thickness (for example, 0.2 μm) corresponding to film thicknesses of the second semiconductor regions SR2-1 to SR2-k to be formed in a subsequent step.

Next, a resist pattern RP1 having a plurality of opening patterns OP11 to OP14 is formed on the insulating film DF1i in a region corresponding to the first semiconductor region SR1.

In a step shown in FIG. 2C, the resist pattern RP1 is used as a mask to process the insulating film by using dry etching through an RIE process, for example. Consequently, a plurality of holes DF11 to DF14 is formed in a region corresponding to the photodiode PD1 in the insulating film DF1. Furthermore, a plurality of holes GF11 to GF14 is formed in the region corresponding to the photodiode PD1 in the gate insulating film GF1 in such a manner that a plurality of regions being a part of the surface SR1a of the first semiconductor region SR1 is exposed. Then, the resist pattern RP1 is removed.

In a step shown in FIG. 2D, the second semiconductor regions SR2-1 to SR2-4 are grown from a plurality of regions exposed from the holes DF11 to DF14 and the holes GF11 to GF14 in the surface SR1a of the first semiconductor region SR1 by an epitaxial growth method or the like. At this time, it is preferable that a growth temperature should be approximately 700° C., for example. It is preferable that the film thicknesses of the second semiconductor regions SR2-1 to SR2-4 should be equal to a total of the film thicknesses of the gate insulating film GF1 and the insulating film DF1, for example.

In the case in which Si₁₋ₓGeₓ (0<x≦1) is selected as the materials of the second semiconductor regions SR2-1 to SR2-k, for instance, a mixed gas of an Si based gas (for example, SiH₄) and a Ge based gas (for example, GeH₄) is used. At this time, a flow ratio of the Si based gas (for example, SiH₄) and the Ge based gas (for example, GeH₄) is regulated depending on a composition ratio of Si₁₋ₓGeₓ (0<x<1) to be formed. The impurity of the first conductivity type may be introduced by the ion implantation or may be introduced by using a gas containing an impurity of a desired conductivity type in-situ in a process for growing the semiconductor layer.

In the step shown in FIG. 1A, the multilayer wiring structure MST1, the color filter CF1 and the microlens ML1 are formed in sequence on the photodiode PD1 and the insulating film DF1. Consequently, the solid-state image sensing device 1 is obtained.

There will be considered the case in which a semiconductor region (for example, Ge) having a higher photoelectric conversion efficiency than the first semiconductor region SR1 is formed in a shape of a layer having an equal width to that of the first semiconductor region SR1 on the first semiconductor region SR1 (for example, Si) in the region SR1 of the first conductivity type in the photodiode PD1. In this case, a contact area of the first semiconductor region SR1 (for example, Si) and the semiconductor layer (for example, Ge) is very large. For this reason, there is a tendency that a crystal defect (dislocation) is apt to be caused on an interface of the first semiconductor region SR1 (for example, with a distance between lattices of 0.543 nm) and a semiconductor layer (for example, with a distance of 0.565 nm between lattices) due to their lattice mismatch, and a density of the crystal defect (dislocation) on their interface exceeds a tolerance. Consequently, there is a tendency that an undesirable current caused by the crystal defect is increased in the photodiode PD1. For example, a junction leakage current leaking through the crystal defect is increased in the photodiode PD1 or an electric charge is trapped into the crystal defect in the photodiode PD1. Consequently, a reduction in a signal or a generation of a current serving as a noise source is caused. As compared with the case in which there is no crystal defect, an S/N radio in an obtained image signal is deteriorated more greatly.

On the other hand, in the first embodiment, the second semiconductor regions SR2-1 to SR2-k formed by a material containing, for example, Si₁₋ₓGeₓ (0<x≦1) as a main component are provided in a shape of islands on the first semiconductor region SR1 formed by a material containing, for example, Si as a main component in the region SR1 of the first conductivity type in the photodiode PD1, respectively. Consequently, it is possible to reduce the contact area of the first semiconductor region SR1 and each of the second semiconductor regions SR2-1 to SR2-k while enhancing the photoelectric conversion efficiency in the photodiode PD1. Therefore, it is easy to keep the density of a crystal defect on their interface within the tolerance. Thus, the photoelectric conversion efficiency can be enhanced so that the undesirable current caused by the crystal defect can be reduced. As a result, it is possible to enhance the S/N ratio in the image signal obtained in the solid-state image sensing device 1.

In the first embodiment, moreover, the second semiconductor regions SR2-1 to SR2-k have a maximum width, in a direction along the surface SR1a of the first semiconductor region SR1, which is equal to or smaller than 0.1 μm. Consequently, the lattice mismatch between the crystal of the first semiconductor region SR1 (for example, a material containing Si as a main component) and that of each of the second semiconductor regions SR2-1 to SR2-k (for example, the material containing Si₁₋ₓGeₓ (0<x≦1) as the main component) can be absorbed into both of them. Consequently, it is possible to suppress the generation of the crystal defect (dislocation) on the interface of the first semiconductor region SR1 and each of the second semiconductor regions SR2-1 to SR2-k.

In the first embodiment, furthermore, an optical absorption coefficient of each of the second semiconductor regions SR2-1 to SR2-k formed by the material containing Si₁₋ₓGeₓ (0<x≦1) as the main component is high as shown in FIG. 9, for example. In particular, a light having a long wavelength which is absorbed into a deep region in the first semiconductor region SR1 (for example, a light having a red color) can be absorbed into each of the second semiconductor regions SR2-1 to SR2-k. Therefore, it is also possible to considerably reduce a depth of the first semiconductor region SR1 more greatly than a junction depth (for example, 3 μm) in the case in which a photoelectric converting portion is constituted by only Si having no second semiconductor regions SR2-1 to SR2-k. In other words, the depth of the region SR1 of the first conductivity type in the photodiode PD1 can be wholly reduced. Therefore, it is possible to obtain a structure which is resistant to color mixing between pixels through an oblique incident light.

In the first embodiment, thus, upper surfaces of the second semiconductor regions SR2-1 to SR2-k constitute light receiving surfaces in addition to the surface SR1a of the first semiconductor region SR1 in the photodiode PD1.

Although there has been illustratively described the case in which the first conductivity type is the N type and the second conductivity type is the P type in the first embodiment, the first conductivity type may be the P type and the second conductivity type may be the N type.

### Second Embodiment

Next, a solid-state image sensing device 200 according to a second embodiment will be described. Portions different from those in the first embodiment will be mainly described below.

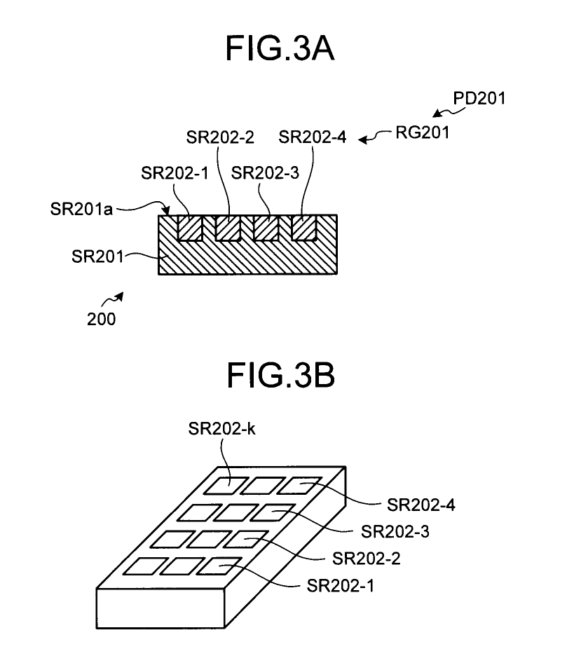

In the second embodiment, a structure in a photodiode PD201 of the solid-state image sensing device 200 is different from that of the first embodiment as shown in FIGS. 3A and 3B.

More specifically, in a region RG201 of a first conductivity type in the photodiode PD201, each of second semiconductor regions SR202-1 to SR202-k is embedded in a portion near a surface SR201a of the first semiconductor region SR201. In this case, a surface SR201a of the first semiconductor region SR201 and an upper surface of each of the second semiconductor regions SR202-1 to SR202-k may form a continuous surface. Alternatively, the upper surface of each of the second semiconductor regions SR202-1 to SR202-k may be higher than the surface SR201a of the first semiconductor region SR201.

Moreover, each of the second semiconductor regions SR202-1 to SR202-k may have a maximum width, in a direction along the surface SR201a of the first semiconductor region SR201, which is equal to or smaller than 0.1 μm, and furthermore, a maximum film thickness which is equal to or smaller than 0.1 μm.

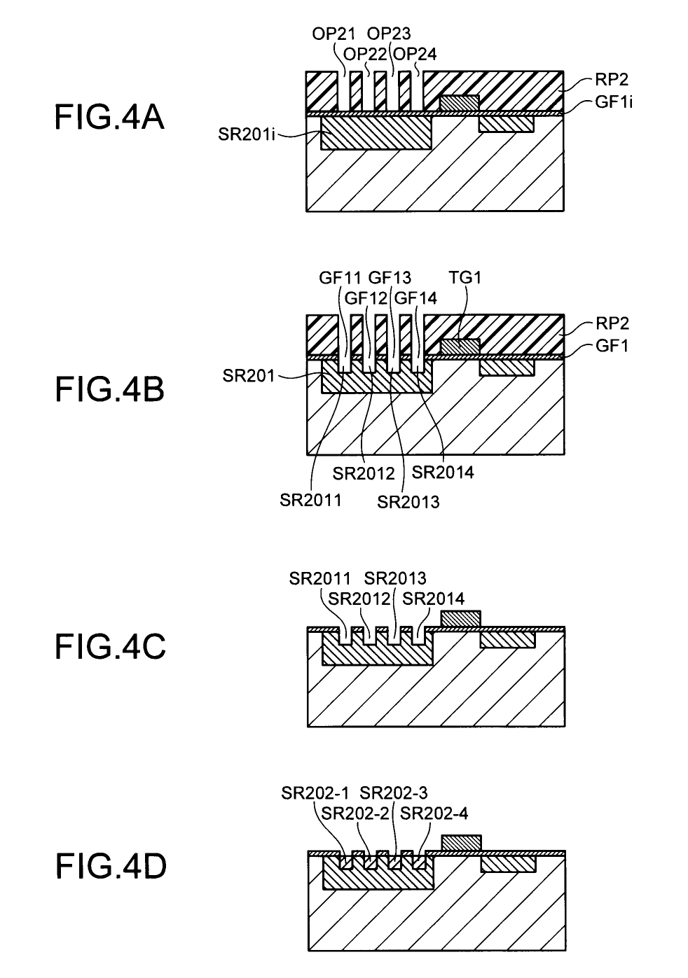

Furthermore, a method of manufacturing the solid-state image sensing device 200 is different from that in the first embodiment, as shown in FIGS. 4A to 4D.

A step shown in FIG. 4A is carried out after the step shown in FIG. 2A. In this step, a resist pattern RP2 having a plurality of opening patterns OP21 to OP24 is formed in a region corresponding to the first semiconductor region SR1 in order to cover the gate insulating film GF1i and the gate electrode TG1.

In a step shown in FIG. 4B, the resist pattern RP2 is used as a mask to carry out etching. The etching may be dry etching through an RIE process, for example. Consequently, a plurality of holes GF11 to GF14 is formed in a region corresponding to the photodiode PD1 in the gate insulating film GF1 in such a manner that the regions to be a part of the surface SR1a of the first semiconductor region SR201i are exposed, and a plurality of concave portions SR2011 to SR2014 is formed in a plurality of regions in which the second semiconductor regions SR202-1 to SR202-4 are to be formed in the first semiconductor region SR201. At this time, a maximum depth of each of the concave portions SR2011 to SR2014 may be set to be equal to or smaller than 0.1 μm.

In a step shown in FIG. 4C, the resist pattern RP2 is removed.

In a step shown in FIG. 4D, the second semiconductor regions SR202-1 to SR202-4 are grown in the concave portions SR2011 to SR2014 exposed through the holes GF11 to GF14 in the first semiconductor region SR1 through an epitaxial process, or the like. At this time, it is preferable that a growing temperature should be approximately 700° C., for example. A film thickness of each of the second semiconductor regions SR202-1 to SR202-4 may be almost equal to a maximum depth of each of the concave portions SR2011 to SR2014 (which is equal to or smaller than 0.1 μm, for example). Alternatively, the film thickness of each of the second semiconductor regions SR202-1 to SR202-4 may be greater than the maximum depth of each of the concave portions SR2011 to SR2014.

As described above, in the second embodiment, each of the second semiconductor regions SR202-1 to SR202-k is embedded in a portion near the surface SR201a of the first semiconductor region SR201 in the region RG201 of the first conductivity type in the photodiode PD201. The structure also makes it possible to reduce the contact area of the first semiconductor region SR1 and each of the second semiconductor regions SR202-1 to SR202-k while enhancing a photoelectric conversion efficiency in the photodiode PD1. Therefore, it is possible to easily keep a density of a crystal defect in their interface within a tolerance. In other words, it is possible to enhance the photoelectric conversion efficiency, thereby reducing the undesirable current caused by the crystal defect. As a result, it is possible to enhance an S/N ratio in an image signal obtained in the solid-state image sensing device 200.

In the second embodiment, moreover, the maximum film thickness of each of the second semiconductor regions SR202-1 to SR202-k may be equal to or smaller than 0.1 μm. In the case in which the maximum film thickness of each of the second semiconductor regions SR202-1 to SR202-k is equal to or smaller than 0.1 μm, it is easier to absorb a lattice mismatch of a crystal of the first semiconductor region SR1 (for example, a material containing Si as a main component) and a crystal of each of the second semiconductor regions SR202-1 to SR202-k (for example, a material containing Si₁₋ₓGeₓ (0<x≦1) as a main component) into both of them. Therefore, it is possible to further suppress a generation of a crystal defect (dislocation) in the interface between the first semiconductor region SR1 and each of the second semiconductor regions SR202-1 to SR202-k.

### Third Embodiment

Next, a solid-state image sensing device 300 according to a third embodiment will be described. In the following, portions different from those in the second embodiment will be mainly described.

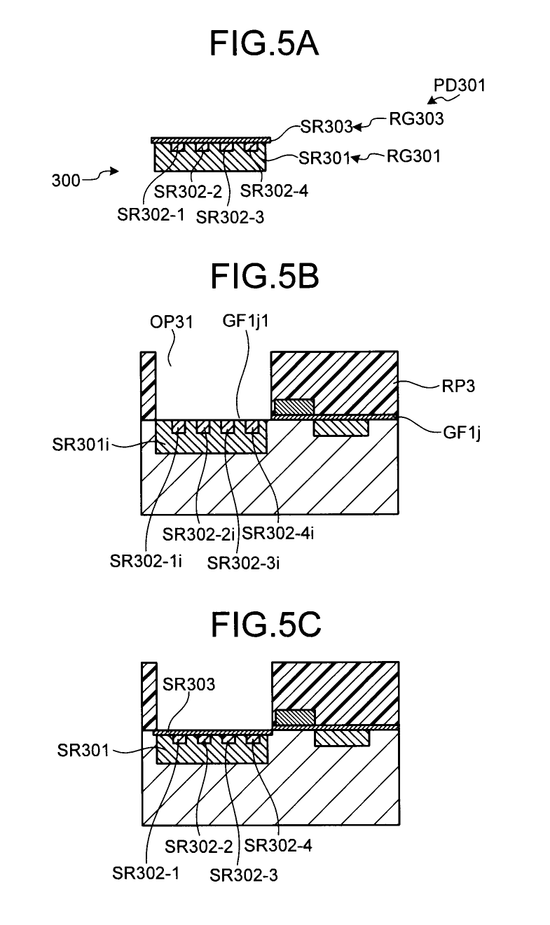

In the third embodiment, a structure in a photodiode PD301 of the solid-state image sensing device 300 is different from that in the second embodiment, as shown in FIG. 5A.

More specifically, in the photodiode PD301, a surface of a region RG301 of a first conductivity type is covered with a region RG303 of a second conductivity type. The region RG303 of the second conductivity type has a third semiconductor region SR303. The third semiconductor region SR303 is formed by a semiconductor containing an impurity of the second conductivity type in a higher concentration than that of the impurity of the second conductivity type in a well region of a semiconductor substrate SB. In other words, in the third semiconductor region SR303, a plurality of regions provided in contact with the second semiconductor regions SR302-1 to SR302-k is formed by the same material (for example, a material containing Si₁₋ₓGeₓ (0<x≦1) as a main component) as that of the second semiconductor regions SR302-1 to SR302-k. In the third semiconductor region SR303, moreover, a lattice-like region provided in contact with the first semiconductor region SR301 is formed by the same material (for example, a material containing Si as a main component) as that of the first semiconductor region RS301, for instance.

Furthermore, it is preferable that a film thickness of the third semiconductor region SR303 should be reduced as greatly as possible (for example, 100 nm).

Moreover, a method of manufacturing the solid-state image sensing device 300 is different from that of the second embodiment in the following respects, as shown in FIGS. 5B and 5C.

A step shown in FIG. 5B is carried out after the step shown in FIG. 4D. In this step, a resist pattern RP3 having an opening pattern OP31 is formed in regions corresponding to a first semiconductor region SR301i and a plurality of second semiconductor regions SR302-1i to SR302-4i in order to cover a gate insulating film GF1 and a gate electrode TG1. Then, the resist pattern RP3 is used as a mask to carry out etching until surfaces of the first semiconductor region SR301i and the second semiconductor regions SR302-1i to SR302-4i are exposed. The etching may be dry etching through an RIE process or wet etching, for example. Consequently, an opening GF1j1 is formed on a gate insulating film GF1j.

In a step shown in FIG. 50, an impurity of the second conductivity type is introduced into the exposed surfaces of the first semiconductor region SR301i and the second semiconductor regions SR302-1i to SR302-4i through ion implantation, solid phase diffusion or the like.

Thereafter, a heat treatment for activating the impurity is carried out. Consequently, a third semiconductor region SR303 containing the impurity of the second conductivity type is formed on the surfaces of the first semiconductor region SR301 and the second semiconductor regions SR302-1 to SR302-4 which contain the impurity of the first conductivity type, respectively.

As described above, in the third embodiment, the surface of the region RG301 of the first conductivity type is covered with the region RG303 of the second conductivity type. Consequently, an electric charge generated in the region RG301 of the first conductivity type can be prevented from being trapped into an interface state (for example, an Si/SiO₂ interface state) present on the surface of the semiconductor substrate SB, resulting in a reduction in a dark current.

### Fourth Embodiment

Next, a solid-state image sensing device 400 according to a fourth embodiment will be described. In the following, portions different from those in the first embodiment will be mainly described.

The fourth embodiment is different from the first embodiment in that the solid-state image sensing device 400 is of a back-side illumination type.

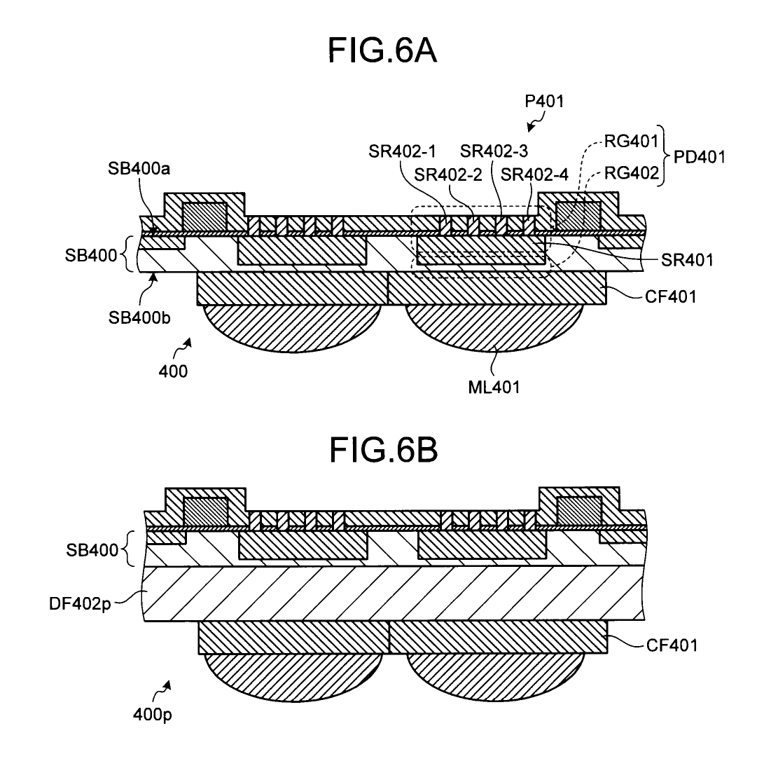

More specifically, in a pixel P401 of the solid-state image sensing device 400, a microlens ML401 and a color filter CF401 are provided on a back face SB400b side of a semiconductor substrate SB400, as shown in FIG. 6A. In other words, the microlens ML401 guides an incident light from the back face SB400b side of the semiconductor substrate SB400 to a region RG401 of a first conductivity type on a surface SB400a side via a region RG402 of a second conductivity type in a photodiode PD401 through the color filter CF401. It is preferable that the semiconductor substrate SB400 should be thinned through back-side polishing. In the case in which the semiconductor substrate SB400 is thinned through the back-side polishing, a lower surface of the region RG402 of the second conductivity type forms a part of the back face SB400b of the semiconductor substrate SB400. Moreover, the region RG402 of the second conductivity type has a thickness smaller than that of a first semiconductor region SR401.

Consequently, a light having a short wavelength which is to be absorbed into a shallow part of bonding is mainly absorbed by the first semiconductor region SR401 formed by a material containing Si as a main component, for example. Lights having middle and long wavelengths to be absorbed into a deep part of the bonding are mainly absorbed into a plurality of second semiconductor regions SR402-1 to SR402-4 formed by a material containing Si₁₋ₓGeₓ (0<x≦1) as a main component, for example.

According to the fourth embodiment, thus, it is possible to enhance a photoelectric conversion efficiency, thereby reducing an undesirable current which is caused by a crystal defect also in the solid-state image sensing device 400 of the back-side illumination type.

A solid-state image sensing device 400p of the back-side illumination type may have a structure in which an insulating film DF402p is provided between the semiconductor substrate SB400 and the color filter CF401. It is possible to obtain such a structure by means of a substrate formed by preparing an SOI substrate and polishing a back face of the SOI substrate to expose an embedded oxide layer.

### Fifth Embodiment

Next, a solid-state image sensing device 500 according to a fifth embodiment will be described. In the following, portions different from those in the first embodiment will be mainly described.

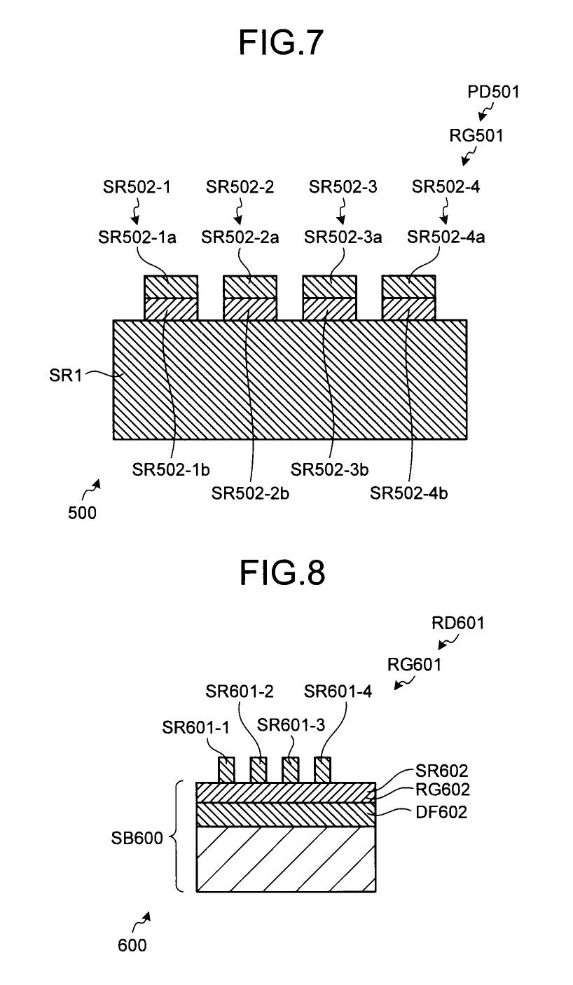

In the fifth embodiment, a structure in a photodiode PD501 of the solid-state image sensing device 500 is different from that of the first embodiment, as shown in FIG. 7.

More specifically, in a region RG501 of a first conductivity type in the photodiode PD501, each of second semiconductor regions SR502-1 to SR502-4 has a higher Ge content rate in an upper part than that in a lower part.

For example, each of the second semiconductor regions SR502-1 to SR502-4 has a multilayer structure, and may have a structure in which the Ge content rate is increased stepwise from a lower layer toward an upper layer. For example, each of the second semiconductor regions SR502-1 to SR502-4 may have a two-layer structure in which upper layers SR502-1a to SR502-4a are laminated on lower layers SR502-1b to SR502-4b, as shown in FIG. 7. In other words, in the case in which the upper layers SR502-1a to SR502-4a are formed by a material containing Si₁₋ₓ₁Geₓ₁ (0<x1<1) as a main component and the lower layers SR502-1b to SR502-4b are formed by a material containing Si₁₋ₓ₂Geₓ₂ (0<x2≦1) as a main component, x1>x2 is established.

Alternatively, each of the second semiconductor regions SR502-1 to SR502-k may have a Ge concentration profile in which the Ge content rate is continuously increased from the lower side toward the upper side, for example.

It is possible to obtain such a structure by growing the second semiconductor regions SR502-1 to SR502-k while increasing a flow ratio of a Ge based gas (for example, GeH₄) to an Si based gas (for example, SiH₄) stepwise or continuously in the step shown in FIG. 2D, for example.

As described above, in the fifth embodiment, each of the second semiconductor regions SR502-1 to SR502-4 has a Ge content rate in the upper part, which is higher than in the lower part. Consequently, it is possible to effectively reduce a lattice mismatch with the first semiconductor region SR1 by decreasing the Ge content rate in the lower part while increasing the Ge content rate in the upper part to effectively enhance a photoelectric conversion efficiency in the photodiode PD501.

### Sixth Embodiment

Next, a solid-state image sensing device 600 according to a sixth embodiment will be described. In the following, portions different from those in the first embodiment will be mainly described.

In the sixth embodiment, a structure in a photodiode PD601 of the solid-state image sensing device 600 is different from that of the first embodiment, as shown in FIG. 8.

More specifically, in a region RG601 of a first conductivity type which is bonded to a region RG602 of a second conductivity type in the photodiode PD601, a plurality of first semiconductor regions SR601-1 to SR601-4 is provided in a shape of islands over a second semiconductor region SR602. In other words, there is employed a structure in which the first semiconductor region containing Si as a main material in the region RG601 of the first conductivity type is replaced with the second semiconductor region formed by a material containing Ge.

It is possible to obtain such a structure by preparing, as a semiconductor substrate SB600, a GOI (Germanium On Insulator) substrate in which an embedded insulating layer (a Ge oxide layer) DF602 and an active layer (a Ge layer) are laminated on a ground region, thereby forming the second semiconductor region SR602 in the Ge layer of the GOI substrate, and furthermore, selectively growing the first semiconductor regions SR601-1 to SR601-4 by a material containing Si as a main component on the second semiconductor region SR602 in the same manner as in the first embodiment.

As described above, also in the sixth embodiment, it is possible to reduce a contact area of the second semiconductor region SR602 and the first semiconductor regions SR601-1 to SR601-4. Therefore, it is easy to keep a density of a crystal defect in their interface within a tolerance. Consequently, it is possible to enhance a photoelectric conversion efficiently, thereby reducing an undesirable current caused by the crystal detect. As a result, it is possible to enhance an S/N ratio in an image signal obtained in the solid-state image sensing device 600.

Moreover, a band barrier is present due to a difference in a bandwidth which is peculiar to a material over an interface of silicon and germanium or the silicon and a silicon layer containing the germanium. A height of the barrier is greatly influenced by a concentration of the germanium, a concentration of an N-type or P-type impurity, an applied voltage or the like. In consideration of such influence, however, it is possible to fetch an electric charge generated in the silicon and the germanium or the silicon layer containing the germanium.

Furthermore, it is also possible to directly form an electrode layer with a transparent conductive film, such as an ITO (Indium Tin Oxide) film in a surface portion of an island-shaped semiconductor region, thereby utilizing the electrode layer to fetch an electric charge in the region of the first conductivity type.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state image sensing device comprising a photodiode in which a semiconductor region of a first conductivity type formed on a substrate and a semiconductor region of a second conductivity type which is different from the first conductivity type is made as a PN junction,
wherein the semiconductor region of the first conductivity type has a first semiconductor region and a plurality of second semiconductor regions,
either of the first semiconductor region and each of the second semiconductor regions is formed by a material containing Si as a main component,
the other of the first semiconductor region and each of the second semiconductor regions is formed by a material containing Si₁₋ₓGeₓ (0<x≦1) as a main component, and
each of the plurality of second semiconductor regions is provided in a shape of an island over the first semiconductor region.

2. The solid-state image sensing device according to claim 1, wherein the first semiconductor region is formed by a material containing Si as a main component, and
each of the second semiconductor regions is formed by a material containing Si₁₋ₓGeₓ (0<x≦1) as a main component.

3. The solid-state image sensing device according to claim 2, wherein the plurality of second semiconductor regions is arranged two-dimensionally over the first semiconductor region.

4. The solid-state image sensing device according to claim 2, wherein each of the plurality of second semiconductor regions takes a shape of a prism.

5. The solid-state image sensing device according to claim 2, wherein each of the plurality of second semiconductor regions takes a shape of a cylinder or an elliptic cylinder.

6. The solid-state image sensing device according to claim 2, wherein each of the plurality of second semiconductor regions is formed to take a convex shape on a surface of the first semiconductor region.

7. The solid-state image sensing device according to claim 6, further comprising an insulating film which covers a surface of the substrate and through which the plurality of second semiconductor regions penetrate.

8. The solid-state image sensing device according to claim 7, wherein the insulating film has a film thickness which corresponds to a height of each of the plurality of second semiconductor regions.

9. The solid-state image sensing device according to claim 2, wherein each of the plurality of second semiconductor regions is embedded in the first semiconductor region.

10. The solid-state image sensing device according to claim 9, wherein the surface of the first semiconductor region and an upper surface of each of the plurality of second semiconductor regions form a continuous surface.

11. The solid-state image sensing device according to claim 9, wherein the upper surface of each of the plurality of second semiconductor regions is higher than the surface of the first semiconductor region.

12. The solid-state image sensing device according to claim 9, further comprising a third semiconductor region of the second conductivity type for covering the surface of the first semiconductor region and an upper surface of each of the plurality of second semiconductor regions.

13. The solid-state image sensing device according to claim 12, wherein, in the third semiconductor region, a region provided in contact with the first semiconductor region is formed by a material containing Si as a main component and each of regions provided in contact with the plurality of second semiconductor regions is formed by a material containing Si₁₋ₓGeₓ (0<x≦1) as a main component.

14. The solid-state image sensing device according to claim 2, wherein the solid-state image sensing device is of a back-side illumination type, and
a lower surface of the semiconductor region of the second conductivity type forms a part of a back face of the substrate.

15. The solid-state image sensing device according to claim 14, wherein the semiconductor region of the second conductivity type is thinner than the first semiconductor region.

16. The solid-state image sensing device according to claim 2, wherein a Ge content rate in an upper part in the second semiconductor region is higher than that in a lower part in the second semiconductor region.

17. The solid-state image sensing device according to claim 16, wherein the second semiconductor region has a multilayer structure and has a structure in which the Ge content rate is increased stepwise from a lower layer toward an upper layer.

18. The solid-state image sensing device according to claim 16, wherein the second semiconductor region has a Ge concentration profile in which the Ge content rate is continuously increased from a lower side toward an upper side.

19. The solid-state image sensing device according to claim 2, wherein each of the plurality of second semiconductor regions has a maximum width, in a direction along a surface of the first semiconductor region, which is equal to or smaller than 0.1 μm.

20. The solid-state image sensing device according to claim 9, wherein each of the plurality of second semiconductor regions has a maximum width, in a direction along the surface of the first semiconductor region, which is equal to or smaller than 0.1 μm, and a maximum thickness which is equal to or smaller than 0.1 μm.
